(19) United States
(12) Patent Application Publication
(10) Pub. No.: US 2025/0218975 A1
(43) Pub. Date: Jul. 3, 2025

(54) WAFER-LEVEL CHIP SCALE PACKAGE SEMICONDUCTOR DEVICES WITH LIGHT BLOCKING MATERIAL AND METHODS

(71) Applicant: TEXAS INSTRUMENTS INCORPORATED, Dallas, TX (US)

(72) Inventors: Daiki Komatsu, Beppu-shi Oita-ken (JP); Masamitsu Matsuura, Beppu-shi Oita-ken (JP)

(21) Appl. No.: 18/399,630

(22) Filed: Dec. 28, 2023

(51) Int. Cl. H01L 23/552; H01L 21/56; H01L 21/78; H01L 23/00

(52) U.S. Cl. CPC H01L 23/552; H01L 21/561; H01L 21/78; H01L 24/05; H01L 24/13; H01L 24/94; H01L 2224/02215; H01L 2224/0401; H01L 2224/13147; H01L 2224/94

(57) ABSTRACT

A described example includes: a semiconductor die having bond pads on a device side surface, having a backside surface opposite the device side surface and having four sides extending between the device side surface and the backside surface; a layer of light blocking material deposited on the device side surface, the light blocking material also covering the four sides; semiconductor material on the exterior of the light blocking material covering the four sides, the semiconductor material spaced from the semiconductor device die by the light blocking material covering the four sides; a backside coating of light blocking tape covering the backside surface; openings in the layer of light blocking material on the device side surface, the openings exposing under-bump material formed on the bond pads; and terminals that are formed by solder bumps or conductive post connects formed on the under-bump material.

### TECHNICAL FIELD

This disclosure relates generally to semiconductor dies, and more particularly to methods for making packaged semiconductor dies in a wafer-level chip scale package (WCSP) process with light blocking material.

### BACKGROUND

The use of WCSP processes to produce completed semiconductor dies at the wafer stage that are ready for mounting is increasing. By producing packaged semiconductor dies at the wafer-level, costs of production are lowered (when compared to packaging individual dies after singulation from the wafers). In an example approach, wafer bumping operations are performed to form conductive columns or pillars, or solder bumps are formed, extending from bond pads on semiconductor dies manufactured on a device side surface of a semiconductor wafer. The wafer bumping operations involve deposition of a seed layer of conductor material over the wafer, patterning the seed layer, plating conductive pillars or bumps using the seed layer, and topping the pillars with solder using solder ball drop and reflow. Solder ball drop, solder reflow, solder stencil, drop on demand or inkjet, or solder plating processes can be used to form solder bumps on the semiconductor wafer.

After the semiconductor wafer is bumped, the individual semiconductor dies can be singulated in a wafer dicing tool. In one approach, a mechanical saw is used to cut through the wafer along scribe lanes between the semiconductor dies and to singulate the devices. In additional approaches, a laser can be used to form distressed regions in a wafer along the scribe lanes, and the wafer can be singulated by breaking stretching a dicing tape supporting the semiconductor dies to singulate the wafer along the lines of stress. Plasma dicing, which chemically etches through the semiconductor wafer along the scribe lanes, can be used.

Certain types of semiconductor dies contain circuitry that is particularly sensitive to light. In an example, a light detection and ranging (LIDAR) system has controller ICs that drive the light sources for the LIDAR system. The controller ICs can be adversely affected by light, since semiconductor materials such as silicon and germanium are inherently photosensitive, and circuits on the die can change characteristics when exposed to light including the infrared (IR) or near infrared (NIR) light used for LIDAR. To prevent any adverse changes in performance of the circuitry in the semiconductor dies, an IR light blocking layer needs to be applied to the backside surface and side surfaces of the WCSP semiconductor dies. The board side or device side of the semiconductor dies may also need to be coated in some applications (the light blocking coating can be referred to as “5-sided” where the board side of the die is not coated, or “6-sided” where the board side of the dies is also coated.)

In one approach to produce the semiconductor dies, “reconstituted” wafers are used. The semiconductor dies are singulated from a semiconductor wafer and then temporarily mounted on a carrier or tape to form a reconstituted wafer with additional space between the semiconductor dies. A light blocking layer is applied to the semiconductor dies and a mechanical saw is used to singulate the covered dies, which are then removed from the reconstituted wafer. In an example process, a mold compound is used. To provide sufficient light blocking, this coating on the sides of the dies needs to be fairly thick to ensure light does not transmit through the sides, which increases the spacing required between devices. Because the mold compound thickness is fairly large, the dies cannot be processed completely at the wafer-level, the extra space needed between adjacent devices required by the mold compound means a reconstituted wafer approach is required. The use of the mold compound also requires mechanical sawing of the reconstituted wafer, as the mold compound cannot be cut through economically using other approaches. Use of mechanical sawing increases spacing required between the devices on the reconstituted wafer.

Use of a reconstituted wafer and the need for repeated dicing processes, and repeated individual die pick and place operations, adds substantial costs to the production of the semiconductor dies, and is undesirable. Use of mechanical dicing also requires larger spaces between device dies (compared to laser dicing or plasma dicing), reducing the available wafer area for producing semiconductor devices, and therefore increasing costs. A cost effective and reliable WCSP process for producing semiconductor dies with a light blocking coating is needed.

### SUMMARY

An example method for making a packaged semiconductor device of an arrangement includes: forming under-bump metallization material on bond pads of semiconductor dies arranged in rows and columns on a device side surface of a semiconductor wafer, the semiconductor dies spaced from one another by scribe lanes, the semiconductor wafer having a backside surface opposite the device side surface; forming trenches extending from the device side surface into but not through the semiconductor wafer along sides of the semiconductor dies, the trenches adjacent the scribe lanes; depositing light blocking material over the device side surface, the light blocking material filling the trenches to form filled trenches and forming a layer of the light blocking material covering the device side surface of the semiconductor wafer; patterning the layer of light blocking material to expose the under-bump metallization material over the bond pads of the semiconductor dies and to expose the scribe lanes between the filled trenches; forming solder bumps on the under-bump metallization material; backgrinding the backside surface to thin the semiconductor wafer and to expose the light blocking material in the filled trenches; depositing a light blocking backside coating tape on the backside surface; dicing the semiconductor wafer along the scribe lanes using either laser dicing or plasma dicing, the dicing leaving semiconductor material edges on the sides of the semiconductor dies; and expanding the semiconductor wafer along the scribe lanes to separate the semiconductor dies from one another to form packaged semiconductor dies.

In another example arrangement, an apparatus includes: a semiconductor die having bond pads on a device side surface, having a backside surface opposite the device side surface and having four sides extending between the device side surface and the backside surface; a layer of light blocking material deposited on the device side surface, the light blocking material also covering the four sides extending between the device side surface; semiconductor material on the exterior of the light blocking material covering the four sides, the semiconductor material spaced from the semiconductor device die by the light blocking material covering the four sides; a backside coating of light blocking tape covering the backside surface; openings in the layer of light blocking material on the device side surface, the openings exposing under-bump material formed on the bond pads; and terminals that are formed by solder bumps or conductive post connects formed on the under-bump material.

In another example, a method for forming wafer-level chip scale packaged semiconductor devices of an arrangement includes: forming under-bump metallization material on bond pads of semiconductor dies arranged in rows and columns on a device side surface of a semiconductor wafer, the semiconductor dies spaced from one another by scribe lanes of less than 50 microns width from die edge to die edge; forming trenches adjacent the scribe lanes extending from the device side surface into but not through the semiconductor wafer along edges of the semiconductor dies; depositing light blocking material over the device side surface of the semiconductor wafer, the light blocking material filling the trenches to form filled trenches and forming a layer of the light blocking material covering the device side surface of the semiconductor dies, the layer of light blocking material having a thickness of about 10 microns or less; patterning the layer of light blocking material to expose the under-bump metallization material over the bond pads of the semiconductor dies and to expose the scribe lanes between the filled trenches; forming solder bumps on the under-bump metallization; backgrinding a backside surface of the semiconductor wafer to thin the semiconductor wafer and to expose the light blocking material in the filled trenches at the backside surface; depositing a light blocking backside coating tape on the backside surface; dicing the semiconductor wafer along the scribe lanes using laser dicing or plasma dicing, the dicing leaving semiconductor material edges along the filled trenches on the sides of the semiconductor dies; and expanding the semiconductor wafer to separate the semiconductor dies from one another to form packaged semiconductor devices.

### BRIEF DESCRIPTION OF THE DRAWINGS

FIGS. 1A-1B illustrate a semiconductor wafer and an individual semiconductor die, respectively.

FIGS. 2A-2H, FIG. 2HH, and FIG. 2I illustrate, in a series of cross-sectional views, selected steps for forming a wafer-level chip scale package (WCSP) semiconductor device of an example arrangement.

FIGS. 3A-3B illustrate, in a cross-sectional view and a plan view, respectively, an example WCSP semiconductor device formed using methods of the arrangements.

FIG. 4 illustrates, in a flow diagram, an example method for forming a WCSP semiconductor device of an arrangement.

### DETAILED DESCRIPTION

Corresponding numerals and symbols in the different figures generally refer to corresponding parts, unless otherwise indicated. The figures are not necessarily drawn to scale.

The term “scribe lane” is used herein. A scribe lane is a portion of semiconductor wafer between semiconductor dies. Sometimes in related literature the term “scribe street” is used. Once processing is finished and the semiconductor devices are complete, the semiconductor devices are separated into individual semiconductor dies by severing the semiconductor wafer along the scribe lanes. The separated dies can then be removed and handled individually for further processing including packaging. This process of removing dies from a wafer is referred to as “singulation” or sometimes referred to as “dicing.” Scribe lanes are arranged on four sides of semiconductor dies and when the dies are singulated from one another, rectangular semiconductor dies are formed. The semiconductor dies have a device side surface, where devices were formed over and in the semiconductor material during semiconductor fabrication, a backside surface opposite the device side surface, and four sides extending between the device side surface and the backside surface. In the arrangements, the six sides of a semiconductor die are covered with light blocking material to form a packaged semiconductor device.

Elements are described herein as “coupled.” As used herein, the term “coupled” includes elements that are directly connected, and elements that are electrically connected even with intervening elements or wires are also coupled.

The term “semiconductor die” is used herein. A semiconductor die can be a discrete semiconductor device such as a bipolar transistor, a few discrete devices such as a pair of power FET switches fabricated together on a single semiconductor die, or a semiconductor die can be an integrated circuit with multiple semiconductor devices such as the multiple capacitors in an A/D converter. The semiconductor die can include passive devices such as resistors, inductors, filters, or active devices such as transistors. The semiconductor die can be an integrated circuit with hundreds or thousands of transistors coupled to form a functional circuit, for example a microprocessor or memory device. The semiconductor die can be a passive device such as a sensor, example sensors include photocells, transducers, and charge coupled devices (CCDs), or can be a micromechanical device, such as a digital micromirror device (DMD) or a MEMS device.

The term “stress induced dislocation” is used herein. In a process referred to as “stealth laser dicing” laser energy is focused into particular locations within a semiconductor wafer. The laser energy melts a portion of the semiconductor material forming polysilicon regions. Because the polysilicon takes a larger area than the semiconductor crystal lattice, forming it induces stress within the semiconductor substrate and dislocates the semiconductor crystal lattice in the region affected by the laser energy, resulting in a stress induced dislocation in the semiconductor wafer. When the semiconductor wafer is then pulled on using a dicing tape, the stress induced dislocations can be propagated and form openings in the semiconductor wafer that eventually extend through the semiconductor wafer, the openings are formed along the scribe lanes and thus form rectangular semiconductor dies. Because the process does not impact the surface of the semiconductor wafer with the laser energy, it is referred to as a “stealth” laser dicing process.

The term “light blocking material” is used. As used herein, light blocking material is a material that prevents transmission of light. “Light” as used herein can be visible or invisible to the human eye. Light can include light of various frequencies, such as visible light of wavelength between 350 nanometers to 750 nanometers, infrared (IR) light from 750 nanometers to 1000 microns, and including near infrared (IR) light from 750 nanometers to 2500 nanometers wavelength. Some light blocking materials are labeled “IR cut” materials and act to block transmission of IR light, while allowing some visible light to pass. Some light blocking material blocks all light of any frequencies. In an example arrangement, light blocking material is used that blocks NIR and IR light up to 90% at low thicknesses, such as less than 10 microns.

The term “light blocking backside material” is used. A light blocking backside material is a material applied to a backside surface of a semiconductor wafer or a semiconductor die, and which blocks light at some frequencies. In an example arrangement, an IR blocking backside tape is used. The IR blocking backside tape blocks light from the backside surface of the semiconductor die.

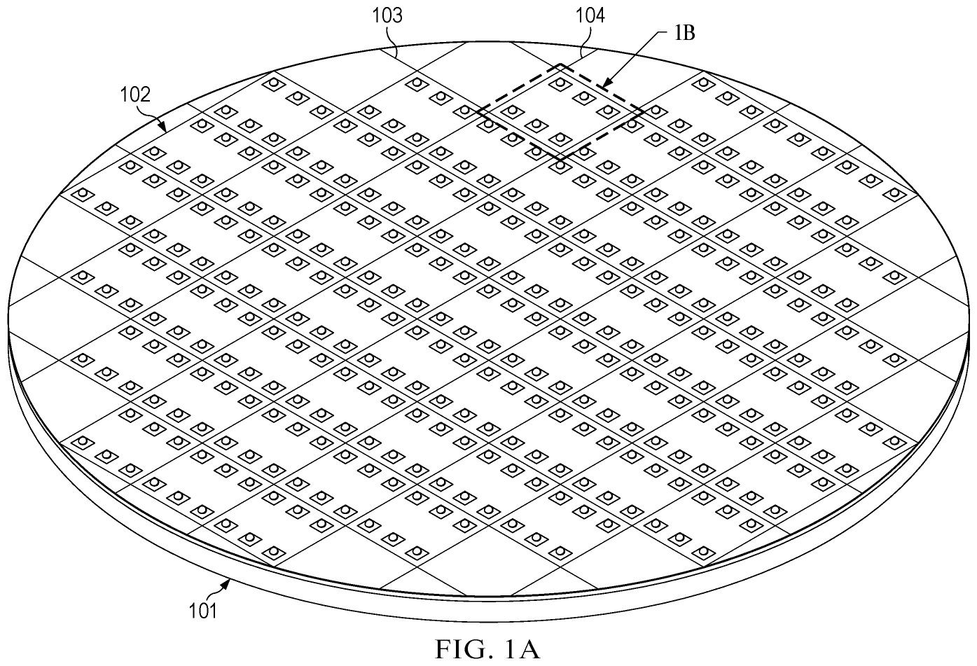

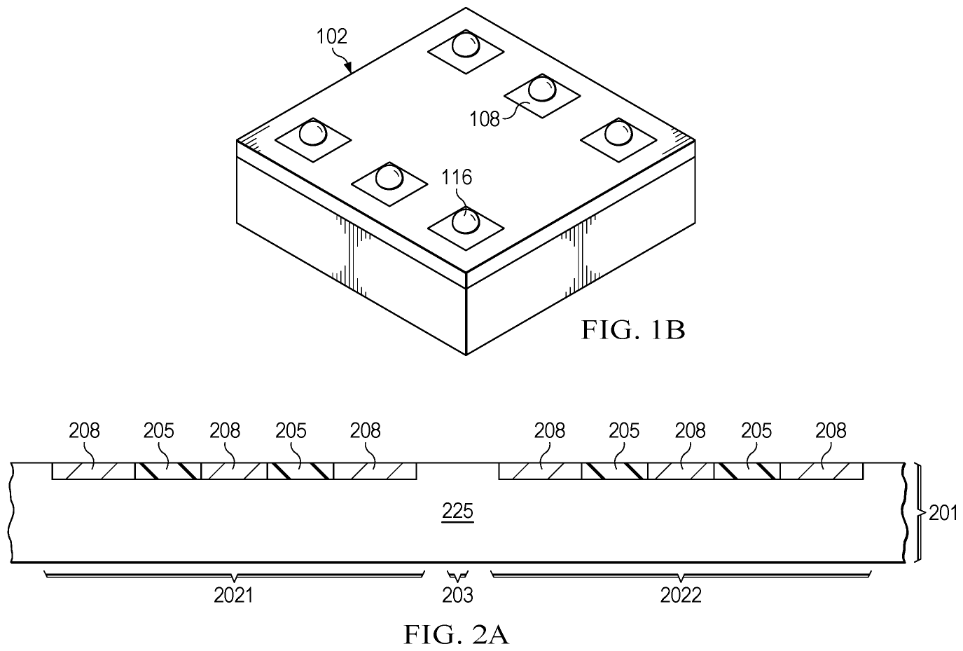

FIGS. 1A-1B illustrate, in projection views, a semiconductor wafer with pillar bumps, and a semiconductor die after singulation from the semiconductor wafer; respectively. In FIG. 1A, a semiconductor wafer 101 is shown after the semiconductor dies 102 are manufactured in a semiconductor fabrication facility (a “fab” or “wafer fab”). In manufacturing semiconductor devices, various processes are used to define passive and active components, and to connect the components to form circuitry on a device side of the semiconductor wafer. The individual dies are replicated across the semiconductor wafer to simultaneously form hundreds or thousands of individual semiconductor dies, increasing throughput. The semiconductor dies 102 are arranged in rows and columns on the semiconductor wafer 101 and are spaced from one another by scribe lanes 103 and 104, which are perpendicular to one another. When a semiconductor wafer is to be singulated by a mechanical sawing operation, the spacing from the device area of one semiconductor die to another semiconductor die has a minimum spacing requirement of about 90 microns. When a laser is used in a stealth dicing operation, the spacing can be reduced to about 30 microns between semiconductor dies, increasing the wafer available for making device dies, and thus lowering costs. When plasma dicing is used, still further reductions in scribe lane area can be attained, further increasing the available wafer area and again, lowering device costs. For semiconductor dies with small area, the area needed for mechanical sawing can be particularly significant, and the number of added devices available when laser or plasma dicing methods are used is also particularly significant. In the arrangements, a WCSP process for solder bumped wafers with an IR blocking coating that are compatible with laser or plasma dicing methods is used, allowing for narrower scribe lanes while eliminating some costly steps in prior approaches including eliminating the use of reconstituted wafers to form the coatings and solder bumps.

In FIG. 1B, an example semiconductor die 102 is shown after it is removed from the semiconductor wafer 101 (see FIG. 1A). The semiconductor die 102 has solder bumps 116 formed on bond pads 108. Use of conductive solder bumps to couple a semiconductor die to a board or module allows for reduced area when compared to a wire bonded packaged semiconductor device, which increases the area needed to mount the device. Wafer-level chip scale (WCSP) packaging also increases throughput by forming the bump connections in parallel, while wire bonding forms electrical connections serially. The elimination of individual die handling, wire bonding, use of a leadframe or package substrate, and molding, further reduces production costs.

As shown in FIG. 1B, the semiconductor die 102 includes solder bumps 116. In an alternative approach, copper pillar bumps can be used. Solder bumps such as solder bumps 116 can be used when the number of connections on the semiconductor die 102 is lower and greater pitch distance between the connections is available, while conductive pillar bumps such as copper pillar bumps can enable finer pitch (less distance between the bond pads) for devices with increased numbers of connections. In the illustrated example arrangements, solder bumps are used in a wafer bumping process. However, in alternative arrangements conductive post connects such as copper pillars can be formed over the bond pads 108 and solder bumps 116 can be formed at distal ends of the conductive post connects, to form copper pillar bumps instead of the solder bumps 116.

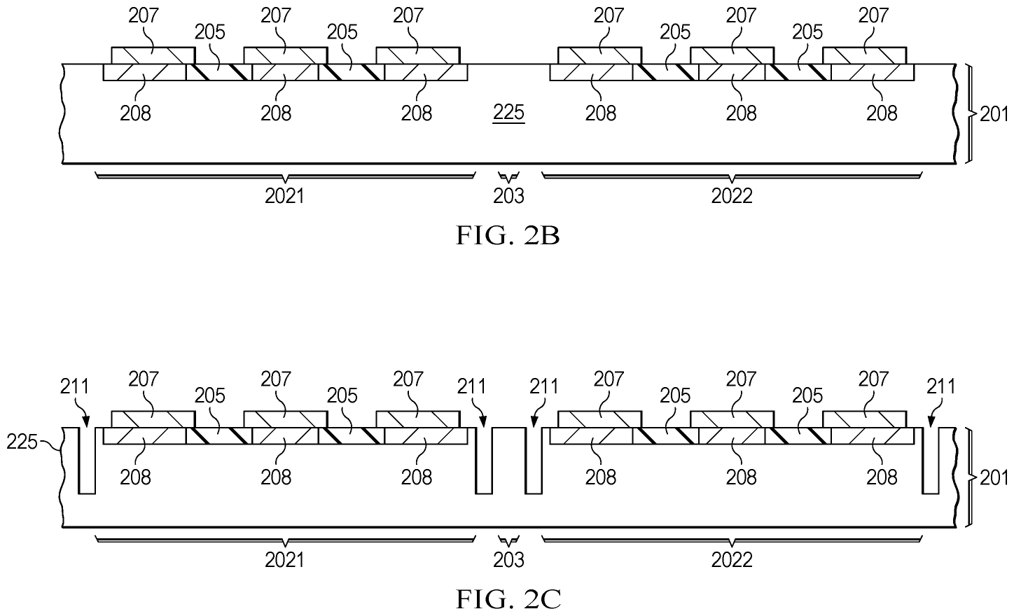

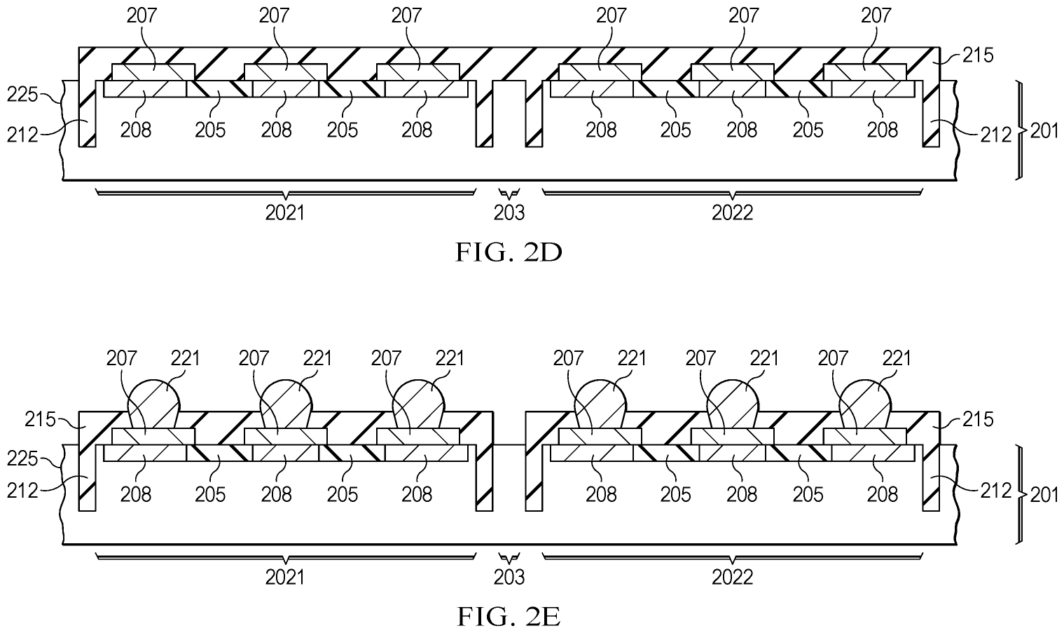

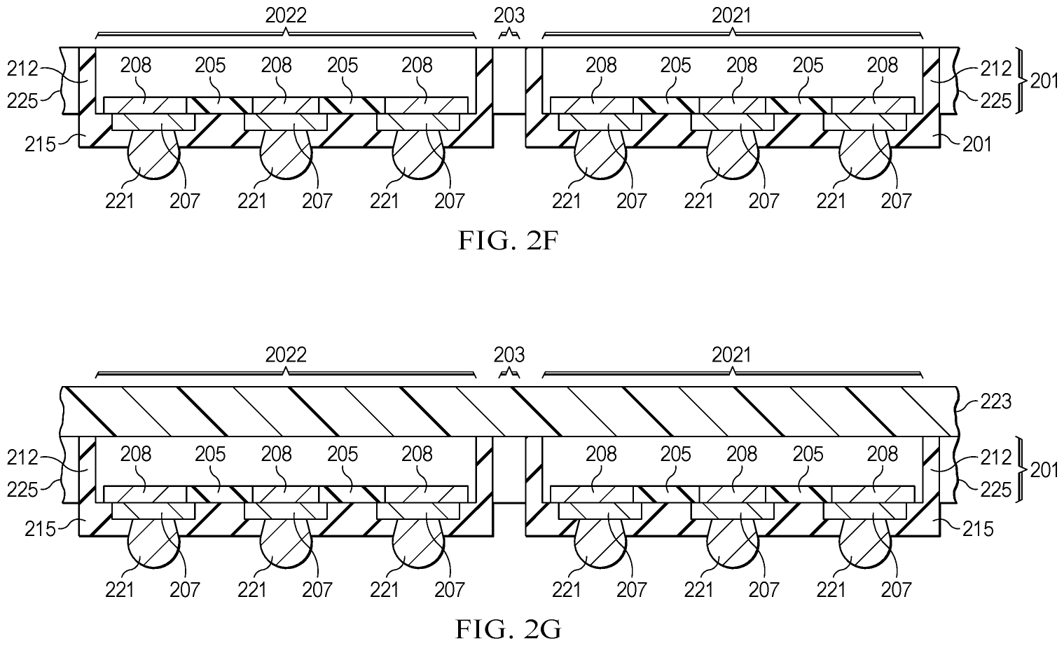

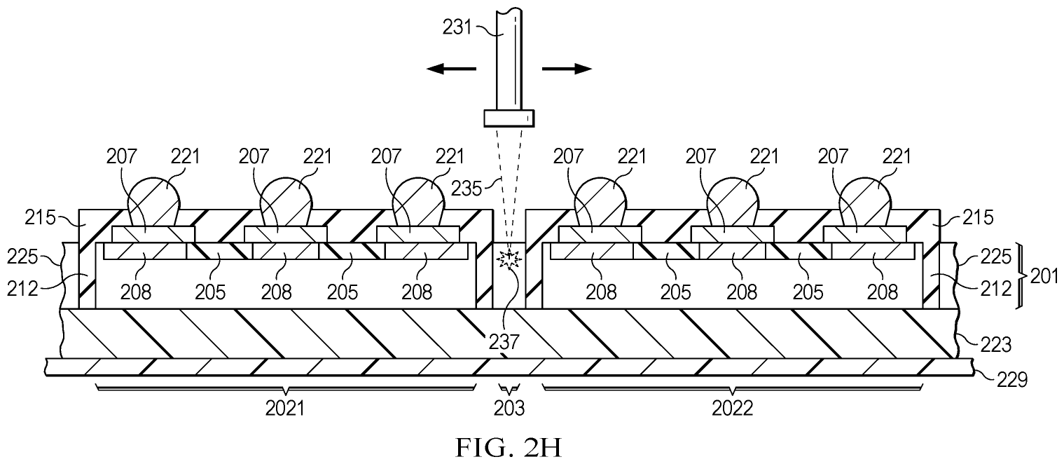

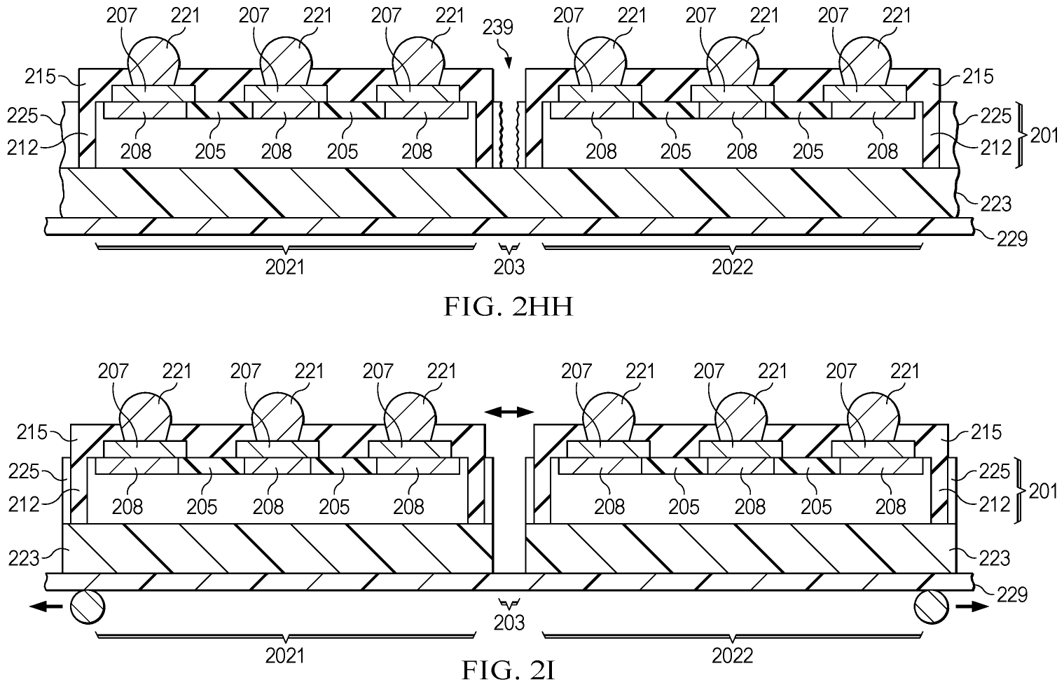

FIGS. 2A-2H, 2HH and 2I illustrate, in a series of cross-sectional views, selected steps in forming an example arrangement. In FIG. 2A, a portion of a semiconductor wafer 201 is shown, which is similar to semiconductor wafer 101 in FIG. 1A, with semiconductor dies 2021 and 2022, which are example replicated semiconductor die devices, spaced by a scribe lane 203. While only two semiconductor dies 2021, 2022 are shown for ease of explanation, in a production case, many semiconductor dies such as tens, hundreds or thousands of semiconductor dies can be arranged on semiconductor wafer 201, in rows and columns (see FIG. 1A, semiconductor wafer 101, and semiconductor dies 102).

The semiconductor dies 2021, 2022 have bond pads 208 that are exposed in openings in a protective passivation layer or dielectric layer 205, which in examples can be a polyimide layer, an oxide, a nitride, or an oxynitride.

FIG. 2B illustrates, in another cross-sectional view, the elements of FIG. 2A after additional processing. In FIG. 2B, semiconductor wafer 201 is shown with under-bump metallization (UBM) 207 formed on the bond pads 208 on the semiconductor dies 2021, 2022. UBM 207 is used to enhance the solder bumping process, to increase the reliability of the physical contact and to ensure a low resistance electrical connection to the bond pads 208. The UBM can be of several layers to reduce migration of ions from the bond pads 208 with a diffusion barrier, to provide a low resistance conductive path, and to increase the solder bump attachment by providing a solderable plating such as tin, nickel, gold, or palladium on the upper surface of the UBM. To form the UBM on the bond pads, a plating process, or several plating processes, are used, with photoresist and photolithography to provide the patterns for the UBM 207.

FIG. 2C illustrates, in another cross-sectional view, the elements of FIG. 2B after additional processing. In FIG. 2C, trenches 211 are shown extending from the device side surface of the semiconductor wafer 201 into, but not through, the semiconductor wafer. The trenches 211 are formed at the edges of the device area for the semiconductor dies 2021, and 2022, on four sides (only two sides of each semiconductor die 2021, 2022 are visible in the cross-section of FIG. 2C). In an example process, the trenches 211 are formed using a silicon etch process. The silicon etch can be, in one particular example, a deep reactive ion etch (“DRIE”) process performed in a plasma processing tool. The DRIE plasma etch can use a fluorine gas as an ion source, and during the etch process the ions bombard the semiconductor wafer in the etch areas to etch the trenches 211. The trenches 211 can be, for example, 90 microns deep. The trenches 211 are between the semiconductor dies 2021, 2022 and border the scribe lane 203, and when the trenches 211 are filled with material (as described below) these will form the sides of the completed devices between a backside surface and the device side surface where the bond pads 208 are formed.

FIG. 2D illustrates, in another cross-sectional view, the elements of FIG. 2C after an additional process. In FIG. 2D, a light blocking material 215 is shown deposited over the device side surface of the semiconductor wafer 201 and patterned to form a coating on the device side of the semiconductor dies 2021, 2022, and extending into and filling the trenches (now referenced as filled trenches 212 to distinguish from the open trenches 211 in FIG. 2C, to cover the sides of semiconductor dies 2021, 2022. The bond pads 208, the UBM material 207 and the dielectric 205 are covered by the light blocking coating 215, as well as the device side surface of semiconductor dies 2021, 2022.

The light blocking material 215 can be patterned using photolithography. In an example, the light blocking material 215 is an IR blocking coating that blocks 95% of near infrared (NIR) light. In an example arrangement, a product labeled SK-7000 that is commercially available from Fujifilm Electronic Materials U.S.A., Inc., North Kingston, Rhode Island, is used. The SK-7000 resist coating is provided in a room temperature liquid for spin coating. Alternative materials that can be used include resists described as “black matrix” resist materials which are light blocking. An alternative IR blocking material useful with the arrangements is a light blocking resist labeled CFPR BK-8310 that is commercially available from Tokyo Ohka Kogyo (TOK) America, Inc., Milpitas, California, U.S.A. The light blocking material 215 forms a layer with relatively small thickness, for example of about 10 microns thick after curing. Useful examples for the light blocking material 215 can between 3 and 10 microns thick. In an example using SK-7000, the material can block 90% of NIR light at a thickness of 3.5 microns. In an example using CFPR BK-8310, the material can block greater than 90% of IR light at a thickness of 1.5 microns. The characteristics of the light blocking resist are such that at these thicknesses, the material blocks about 90% of the NIR light. Because the material has a relatively small thickness, the light blocking material formed in filled trenches 212 can block light from the sides of the semiconductor dies 2021, 2022 with the filled trenches 212 being about 10 microns wide.

In an example spin-coating process that is useful in forming the arrangements, a pre-wetting solution having relatively low viscosity and relatively low specific gravity is applied to the semiconductor wafer in a spin coating tool. After an initial application of the pre-wet material, the pre-wet material fills the trenches (see 211 in FIG. 2C) by capillary action. A hold spin coating cycle at a low RPM of about 30 RPM is performed to stabilize the pre-wet material. The IR blocking material is then dispensed onto the spinning wafer. The IR blocking material is of higher viscosity and greater specific gravity than the pre-wet material, and during a low RPM cycle of about 30 RPM, displaces the pre-wet material from the trenches 211 and fills the trenches, and also coats the device side surface of the semiconductor wafer 201, including the bond pads 208 (see filled trenches 212 in FIG. 2D). After a second hold cycle, a higher RPM cycle of about 1000 RPM is used to make the thickness of the IR blocking material 215 uniform across the device side surface of the wafer, while displacing any remaining prewetting material. A post-apply bake cycle is performed. Later, after patterning steps are completed, a thermal cure is performed to harden the patterned IR blocking material to a solid state.

FIG. 2E illustrates, in a further cross-sectional view, the elements shown in FIG. 2D after additional processing. A photolithographic patterning step removes the light blocking material 215 from the scribe lanes 203 and forms openings exposing the UBM material 207 on the bond pads 208. A thermal cure then hardens the light blocking material 215. In FIG. 2E, solder bumps 221 are shown after being deposited onto the UBM material 207 on the bond pads 208. The semiconductor dies 2021, 2022 in FIG. 2D are shown oriented with the device side surface facing upwards. The light blocking material 215 is patterned to expose the UBM material 207 over each of the bond pads 208.

In one example process that can be used to deposit solder balls 221, a flux material is first deposited on the UBM material 207 using a stencil mask. Solder ball are placed on the flux material using the stencil mask. The solder balls are then heated to bond to the UBM and reflow into solder bumps 221 shaped as shown in FIG. 2E. The surface is then cleaned to remove unused or excess flux material. Alternative processes for forming the solder bumps 221 include vacuum solder ball drop deposition and solder plating processes.

FIG. 2F illustrates, in a further cross-section, the elements of FIG. 2E after additional processing. In FIG. 2F, the semiconductor wafer 201 is rotated to place the bond pads 208 on the device side downwards, for backside processing. The device side surface is temporarily mounted to a removable surface support tape (not shown for simplicity of illustration) that temporarily supports the devices and protects the solder bumps 221. In FIG. 2F, the semiconductor wafer 201 is shown after a backside grinding process was performed to thin the semiconductor wafer 201 and to expose the filled trenches (now 212, the trenches 211 were filled with the light blocking material 215 in a prior step to form filled trenches 212) at the backside. The light blocking material 215 in the filled trenches 212 will eventually form coated sides of the semiconductor dies 2022, 2021 when the dies are singulated from the semiconductor wafer 201 in a later step. Backgrinding of the semiconductor wafer 215 can be done using a chemical-mechanical polishing (“CMP”) process or other wafer thinning process. In an example the filled trenches 212 are about 90 microns deep, and after thinning in the backgrinding process, the semiconductor wafer 201 is about 90 microns thick so that the light blocking material 215 in the filled trenches 212 is exposed on the backside surface of the semiconductor wafer.

FIG. 2G illustrates, in another cross-sectional view, the elements of FIG. 2F after additional processing. In FIG. 2G, a light blocking backside coating material 223 is shown applied to the backside of the semiconductor wafer 201, and contacts the exposed filled trenches 212. In an example arrangement, the light blocking backside coating material 223 is an IR blocking backside tape. By use of the novel methods to form the arrangements, each of the six sides of the semiconductor dies, including the backside surface, the device side surface, and each of four sides between the device side surface and the backside surface, are covered in a light blocking material in a chip scale package.

The backside coating material 223 can be applied as a flexible film in a film laminating tool, and after lamination, can be thermally cured to form a solid layer. One IR blocking backside material that is useful with the arrangements is a product labeled “ADWILL LC TAPE” that is commercially available from LINTEC OF AMERICA, INC., Phoenix, Arizona U.S.A. ADWILL LC TAPE is a backside protection tape that is applied by lamination and subsequently cured to form a solid layer, and is a light blocking film. In useful examples the ADWILL LC TAPE is between 20-30 microns in thickness. In an alternative approach, a liquid (at room temperature) backside coating can be applied to the backside surface and cured. Use of a backside coating tape has an advantage over liquid materials in that the uniformity of the layer thickness is ensured across the semiconductor wafer. Thermal cure and UV cure backside coating tapes that can be used are commercially available from LINTEC OF AMERICA, INC. Additional backside protection tapes useful with the arrangements are available from NITTO INC., Teaneck, New Jersey, U.S.A., and FURUKAWA ELECTRIC CO., LTD., of Tokyo, Japan.

FIG. 2H illustrates the elements of FIG. 2G, now rotated to have the device side with the bond pads 208 of the semiconductor wafer 201 facing upwards, FIG. 2H illustrates a laser dicing process. A dicing tape 229 is applied to the backside coating material 223 on the semiconductor wafer 201 to support the devices during and after dicing. In FIG. 2H, a laser tool 231 is shown traversing scribe lane 203. The laser tool 231 can focus the laser beam 235 at various depths within the semiconductor wafer 201 to form stress induced dislocation regions. The laser energy forms stress dislocation regions within the semiconductor wafer 201 along the scribe lane 203. Because the laser does not cut or ablate the surface of the semiconductor wafer 201, this process is referred to as a “stealth” laser dicing process. By making multiple passes with the laser beam, sufficient stress dislocation areas can be caused in the semiconductor wafer 201 that enable the semiconductor dies 2021, 2022 to be pulled apart along the scribe lanes 203 (in an expansion process described further below).

FIG. 2HH illustrates, in another cross-sectional view, the results of an alternative dicing process, using plasma dicing. In plasma dicing, a silicon etch process using deep reactive ion etching (DRIE) in a plasma chamber, for example using the “Bosch” process, is performed along the scribe lanes (see scribe lane 203) to etch through the semiconductor wafer 201. In the Bosch process, repeated cycles of a mostly isotropic semiconductor etch are performed using a process gas that ionizes in the plasma chamber, such as a fluorine gas, and switching between a fluorine-based deposition gas and a fluorine based etching gas. Between etch cycles, a deposition is performed in the same plasma chamber to line and condition the sidewalls of the previously etched portions of the opening, so that overall, the Bosch etch process (generally isotropic) becomes more anisotropic. The sidewalls of the opening 239 in the semiconductor wafer 201 from the plasma dicing process appear “scalloped” due to the repeated plasma etch and sidewall plasma deposition steps.

FIG. 2HH illustrates the semiconductor wafer 201 after the plasma dicing step opens the semiconductor material in scribe lane 203 to from opening 239. In an example process, the plasma dicing was continued through the thickness of the semiconductor wafer 201 until the backside coating tape 223 is exposed, and can continue into the backside coating tape to make the fracture of the backside coating tape 223 in a subsequent expansion step easier, but as shown in FIG. 2HH the plasma dicing step can also stop before etching into the backside coating tape 223.

As described above, in the arrangements, the trenches 212 are filled with light blocking material that allows the trenches to be about 10 microns wide and block substantially all of the IR light. The narrow trench width of the arrangements enables use of a narrow scribe lane, in conjunction with laser or plasma dicing, of about 40 microns die edge to die edge for laser dicing, or 30 microns die edge to die edge for plasma dicing. This compares to a scribe lane width of about 90 microns die edge to die edge with mechanical dicing.

In FIG. 2I, the elements shown in FIG. 2H or FIG. 2HH are shown in another cross-sectional view to illustrate a die singulation operation by expansion. The dicing tape 229 is designed to be stretched in all directions using a dicing tape expansion tool, which applies tensile stress to the semiconductor wafer 201 and the backside coating material 223 by stretching dicing tape 229. Some dicing tapes are configured to be expanded in a cooling process, at low temperatures. When laser dicing is used (see FIG. 2H, for example) the semiconductor wafer 201 breaks apart along the scribe lanes 203 due to the stress dislocations formed by the laser in the laser dicing tool 231. In contrast to the mechanical sawing processes used in prior approaches, laser dicing causes less chipping and edge damage to the semiconductor dies, improving yields. In addition, the laser dicing process can be performed using narrower scribe lanes (when compared with the scribe lane widths required for mechanical sawing), in an example process the die edge to die edge scribe lane width can be as low as 30 microns, (compared to a minimum of about 90 microns for mechanical sawing.) This reduced scribe lane distance increases the amount of semiconductor wafer available for dies, increasing yield and reducing costs for each semiconductor die. Plasma dicing can also be used (see FIG. 2HH) and the semiconductor wafer and dicing tape can be expanded to space the semiconductor dies apart after plasma dicing, breaking the backside coating tape 223 along the scribe lanes 203. Plasma dicing requires even less scribe lane width than laser dicing, further increasing yields.

The dicing tape 229 temporarily adheres to the LC tape 223 which also shears during the expansion along scribe lanes 203. Once the semiconductor dies 2021, 2022 are separated from one another by the wafer expansion, a pick and place tool can remove the individual semiconductor dies 2021, 2022 for use. In one approach, a UV cure is used to release the dicing tape 229 from the backside coating 223 on the backside surface of the semiconductor dies. Other types of dicing tapes can be used, such as peelable dicing tapes.

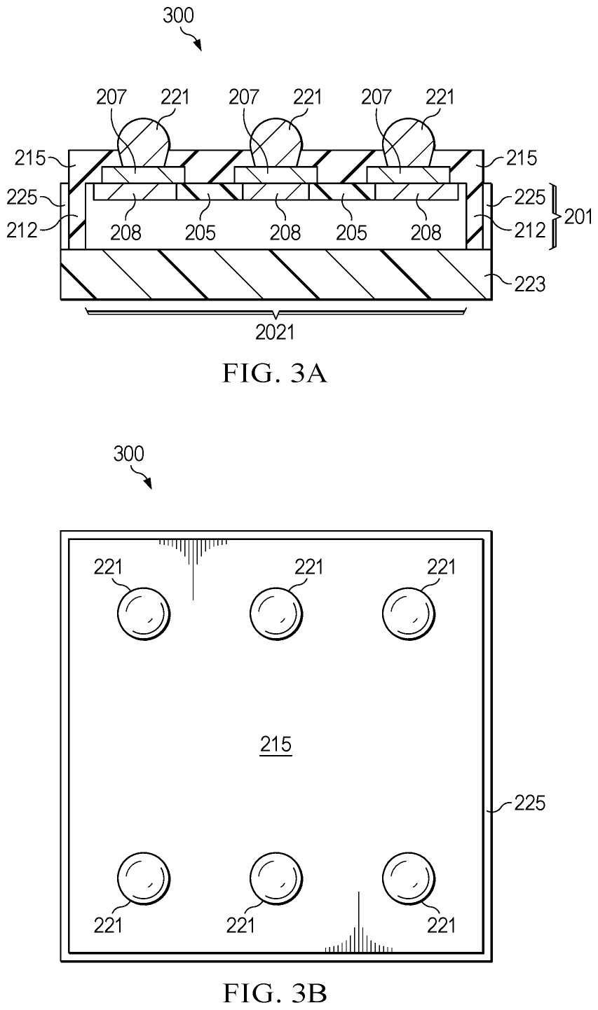

FIGS. 3A-3B illustrate, in a cross-sectional view and a plan view, respectively, a completed semiconductor device 300 including semiconductor die 2021 from FIG. 2I. The semiconductor die 2021 is shown oriented with the solder bumps 221 facing upwards. When the semiconductor device 300 is mounted to a circuit board or module, it is mounted with the solder bumps 221 in contact with conductive lands on the board, and a solder reflow step is used to melt the solder bumps 221 to form solder joints (not shown) to the board. The vertical sides (as device 300 is oriented in FIG. 3A) of the semiconductor device 300 have semiconductor material 225 exposed from the IR blocking layer 215. This semiconductor material 225 on the sides is spaced from the semiconductor die 2021 by the coating 215 and is not in contact with the semiconductor die 2021 but is isolated from it. Referring to FIG. 2H, the semiconductor material 225 is left between the filled trenches 212 which form the sides from the IR blocking material 215, along the scribe lanes after the semiconductor die is singulated in the laser dicing process.

FIG. 3B illustrates the semiconductor device 300 of FIG. 3A, in a plan view from the board side, looking towards the device side surface with solder bumps 221. The IR blocking layer 215 is shown covering the device side surface of the semiconductor die 2021 (not visible, as it is covered by the IR blocking layer 215 in this view). The semiconductor material 225 is shown on the exterior of the IR blocking layer 215 on each vertical side of the semiconductor device 300. Because the backside surface (not visible in FIG. 3B, see FIG. 3A) is coated with IR blocking backside material, such as LC backside tape (see 223 in FIG. 2I) the semiconductor die 2021 is now covered on six sides by IR blocking material, and the semiconductor device 300 is advantageously formed using the WCSP process of the arrangements, without the need for individual semiconductor die handling, and without the need for forming a reconstituted wafer, lowering costs. Use of a laser or plasma dicing method increases the semiconductor wafer area available for dies by allowing for narrower scribe lanes (when compared to wafers arranged for mechanical dicing), further increasing die yields and lowering costs.

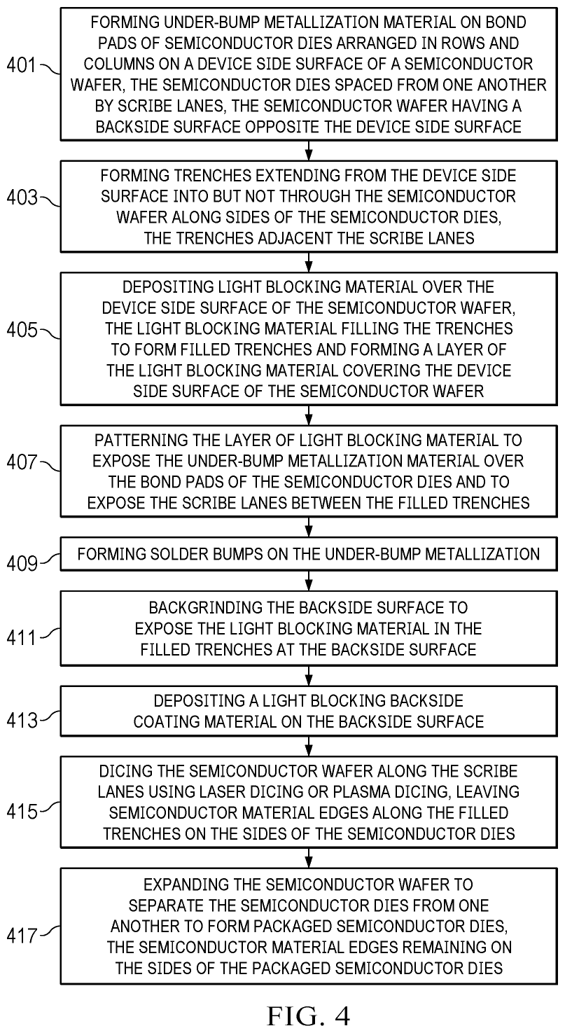

FIG. 4 illustrates, in a flow diagram, a method for forming packaged semiconductor devices of an arrangement. In FIG. 4, the method begins at step 401, where under-bump metallization is formed on bond pads of semiconductor dies arranged in rows and columns on a device side surface of a semiconductor wafer, the semiconductor dies spaced from one another by scribe lanes, the semiconductor wafer having a backside surface opposite the device side surface. (See, for example, semiconductor wafer 201 in FIG. 2B, with under-bump metallization 207 formed on bonds 208 for semiconductor dies 2021, 2022 spaced by a scribe lane 203).

In step 403, the method continues by forming trenches extending from the device side surface into but not through the semiconductor wafer along sides of the semiconductor dies, the trenches adjacent the scribe lanes. (See, for example, trenches 211 extending into the semiconductor wafer 201 on the sides of the semiconductor dies 2021, 2022, and adjacent the scribe lane 203.)

In step 405, the method continues by depositing light blocking material over the device side surface of the semiconductor wafer, the light blocking material filling the trenches to form filled trenches and forming a layer of the light blocking material covering the device side surface of the semiconductor wafer. (See, for example, the light blocking material 215 deposited on the device side surface of semiconductor wafer 201 in FIG. 2D, and filling trenches to form filled trenches 212).

In step 407, the method continues by patterning the layer of light blocking material to expose the under-bump metallization material over the bond pads of the semiconductor dies and to expose the scribe lanes between the filled trenches. (See, for example, the light blocking material in FIG. 2E, and the openings over the scribe lane 203, and the opening in the light blocking material 215 exposing under-bump metallization 207.)

The method continues to step 409, where solder bumps are formed on the under-bump metallization (see FIG. 2E, solder bumps 221 formed on under-bump metallization 207).

In step 411, the method continues by backgrinding the backside surface expose the light blocking material in the filled trenches at the backside surface. (See, for example, FIG. 2F showing the semiconductor wafer 201 after backgrinding, with trenches 212, the filled trenches, exposed at the backside surface opposite the device side surface of semiconductor wafer 201).

In step 413, the method continues by depositing a light blocking backside coating material on the backside surface. (See, for example, FIG. 2G, where the light blocking backside coating material 223 is shown on the backside surface of the semiconductor wafer. The backside coating material 223 contacts the light blocking material 215 on the device side surface of the semiconductor wafer 201).

By use of the arrangements, the device side surface and the sides of the semiconductor dies 2021, 2022 are covered by the light blocking material on the device side surface, while the backside surface of the semiconductor dies 2021, 2022 are covered by the light blocking backside coating material, so that all six sizes of the semiconductor dies, the device side surface, the opposite backside surface, and the sides between the device side surface and the backside surface, are covered by light blocking material.

In step 415, the method continues by dicing the semiconductor wafer along the scribe lanes using laser dicing or plasma dicing, leaving semiconductor material edges along the filled trenches on the sides of the semiconductor dies. (See, for example, the laser dicing shown by laser beam 235 applied to the semiconductor wafer 201 in the scribe lane 203 between the filled trenches 212 in FIG. 2H, and the results of a plasma dicing process shown in FIG. 2HH in scribe lane 203 between filled trenches 212, where an opening 239 was formed along the scribe lane, leaving semiconductor material along the sides of the semiconductor dies 2021, 2022.

In step 417, the method continues by expanding the semiconductor wafer to separate the semiconductor dies from one another to form packaged semiconductor dies, the semiconductor material edges remaining on the sides of the packaged semiconductor dies. (See, for example, the expansion process illustrated in FIG. 2I, where the dicing tape 229 adhered to the backside coating material 223 is stretched to expand the semiconductor wafer 201 and the backside coating material 223, and semiconductor material edges 225 are shown on the sides of the packaged semiconductor dies 2021, 2022.) The semiconductor dies 2021, 2022 have light blocking material on all sides of the semiconductor dies, that is, six sides; the device side surface where the solder bumps 221 form terminals, the opposite backside surface, and the four sides extending between the device side surface and the device side surface. The packaged semiconductor dies have semiconductor material on the edges of the sides (see, for example, FIGS. 3A-3B, semiconductor material 225).

Modifications and variations are contemplated and can be made in the described arrangements, and other alternative arrangements are possible that are within the scope of the claims.

What is claimed is:

1. A method for making a packaged semiconductor device, comprising:
forming under-bump metallization material on bond pads of semiconductor dies arranged in rows and columns on a device side surface of a semiconductor wafer, the semiconductor dies spaced from one another by scribe lanes, the semiconductor wafer having a backside surface opposite the device side surface;
forming trenches extending from the device side surface into but not through the semiconductor wafer along sides of the semiconductor dies, the trenches adjacent the scribe lanes;
depositing light blocking material over the device side surface, the light blocking material filling the trenches to form filled trenches and forming a layer of the light blocking material covering the device side surface of the semiconductor wafer;
patterning the layer of light blocking material to expose the under-bump metallization material over the bond pads of the semiconductor dies and to expose the scribe lanes between the filled trenches;
forming solder bumps on the under-bump metallization material;
backgrinding the backside surface to thin the semiconductor wafer and to expose the light blocking material in the filled trenches;
depositing a light blocking backside coating tape on the backside surface;
dicing the semiconductor wafer along the scribe lanes using either laser dicing or plasma dicing, the dicing leaving semiconductor material edges on the sides of the semiconductor dies; and
expanding the semiconductor wafer along the scribe lanes to separate the semiconductor dies from one another to form packaged semiconductor dies.

2. The method of claim 1, wherein after expanding the semiconductor wafer along the scribe lanes to separate the semiconductor dies from one another to form packaged semiconductor dies, the light blocking material covers the device side surface and four sides that extend perpendicularly from the device side surface to the backside surface of the packaged semiconductor dies, and the backside surface is covered with the light blocking backside coating tape, so that all external surfaces of the packaged semiconductor dies are covered with light blocking material.

3. The method of claim 1, wherein dicing the semiconductor wafer along the scribe lanes using either laser dicing or plasma dicing further comprises:
using a stealth laser dicing process, focusing a laser beam into the semiconductor wafer beneath the device side surface, and traversing the semiconductor wafer along the scribe lanes with the laser beam to form stress dislocation regions within the semiconductor wafer.

4. The method of claim 1, wherein dicing the semiconductor wafer along the scribe lanes using either laser dicing or plasma dicing further comprises performing a plasma dicing process in the scribe lanes of the semiconductor wafer to etch through the semiconductor wafer in the scribe lanes to expose the light blocking backside coating tape.

5. The method of claim 1, wherein depositing a layer of light blocking material over the device side surface of the semiconductor dies on the semiconductor wafer further comprises:
dispensing a liquid pre-wet material onto the semiconductor wafer in a spin-coating process;
using a first spin speed, allowing the pre-wet material to fill the trenches;
dispensing liquid light blocking material onto the semiconductor wafer;
using a second spin speed, displacing the pre-wet material and filling the trenches with the light blocking material;
using a third spin speed greater than the first spin speed, making the thickness of the light blocking material on the device side surface uniform; and
thermally curing the liquid light blocking material to form the layer of light blocking material.

6. The method of claim 1, wherein depositing a light blocking backside coating tape on the backside surface further comprises:
attaching a first side of the light blocking backside coating tape to the backside surface of the wafer; and
thermally curing the light blocking backside coating tape.

7. The method of claim 1, wherein depositing a light blocking backside coating tape on the backside surface further comprises depositing a backside coating tape that blocks infrared light.

8. The method of claim 7, wherein depositing a backside coating tape that blocks infrared light further comprises depositing ADWILL LC backside coating tape from LINTEC OF AMERICA, INC.

9. The method of claim 1, wherein depositing light blocking material over the device side surface of the semiconductor wafer further comprises depositing a material that blocks infrared light.

10. The method of claim 9 wherein depositing a material that blocks infrared light further comprises depositing a black matrix resist.

11. The method of claim 10, wherein depositing a material that blocks infrared light further comprises depositing SK-7000 resist material from Fujifilm Electronic Materials U.S.A., Inc., or depositing CFPR BK-8310 resist material Tokyo Ohka Kogyo (TOK) America, Inc., Milpitas, California, U.S.A.

12. An apparatus, comprising:
a semiconductor die having bond pads on a device side surface, having a backside surface opposite the device side surface and having four sides extending between the device side surface and the backside surface;
a layer of light blocking material deposited on the device side surface, the light blocking material also covering the four sides extending between the device side surface;
semiconductor material on the exterior of the light blocking material covering the four sides, the semiconductor material spaced from the semiconductor device die by the light blocking material covering the four sides;
a backside coating of light blocking tape covering the backside surface;
openings in the layer of light blocking material on the device side surface, the openings exposing under-bump material formed on the bond pads; and
terminals that are formed by solder bumps or conductive post connects formed on the under-bump material.

13. The apparatus of claim 12, wherein the terminals that are formed by solder bumps or conductive post connects formed on the under-bump material further comprise:
copper pillars formed on the under-bump material and extending away from the device side surface of the semiconductor die to a distal end; and
solder bumps formed on the distal end of the copper pillars, the copper pillars and the solder bumps forming copper pillar bumps.

14. The apparatus of claim 12, wherein terminals that are formed by solder bumps or conductive post connects formed on the under-bump material are solder bumps formed by a solder ball drop and reflow process.

15. The apparatus of claim 12, wherein the layer of light blocking material and the backside coating of light blocking material block infrared light.

16. The apparatus of claim 12, wherein the layer of light blocking material comprises a black matrix resist.

17. The apparatus of claim 16, wherein the layer of light blocking material comprises an infrared blocking resist.

18. The apparatus of claim 17, wherein the layer of light blocking material comprises SK-7000 resist material from Fujifilm Electronic Materials U.S.A., Inc., or CFPR BK-8310 resist material from Tokyo Ohka Kogyo (TOK) America, Inc.

19. The apparatus of claim 12, wherein the backside coating of light blocking tape comprises Adwill LC backside coating tape from LINTEC OF AMERICA, INC.

20. A method for forming wafer-level chip scale packaged semiconductor devices, comprising:
forming under-bump metallization material on bond pads of semiconductor dies arranged in rows and columns on a device side surface of a semiconductor wafer, the semiconductor dies spaced from one another by scribe lanes of less than 50 microns width from die edge to die edge;
forming trenches adjacent the scribe lanes extending from the device side surface into but not through the semiconductor wafer along edges of the semiconductor dies;
depositing light blocking material over the device side surface of the semiconductor wafer, the light blocking material filling the trenches to form filled trenches and forming a layer of the light blocking material covering the device side surface of the semiconductor dies, the layer of light blocking material having a thickness of about 10 microns or less;
patterning the layer of light blocking material to expose the under-bump metallization material over the bond pads of the semiconductor dies and to expose the scribe lanes between the filled trenches;
forming solder bumps on the under-bump metallization;
backgrinding a backside surface of the semiconductor wafer to thin the semiconductor wafer and to expose the light blocking material in the filled trenches at the backside surface;
depositing a light blocking backside coating tape on the backside surface;
dicing the semiconductor wafer along the scribe lanes using laser dicing or plasma dicing, the dicing leaving semiconductor material edges along the filled trenches on the sides of the semiconductor dies; and
expanding the semiconductor wafer to separate the semiconductor dies from one another to form packaged semiconductor devices.

21. The method of claim 20, wherein expanding the semiconductor wafer to separate the semiconductor dies from one another to form packaged semiconductor devices further comprises: forming the packaged semiconductor devices having the layer of light blocking material over the device side surface, having the light blocking backside coating tape on the backside surface opposite the device side surface, and having the light blocking material on the four sides between the device side surface and the backside surface, whereby exterior surfaces of the packaged semiconductor devices are covered with light blocking material.

22. The method of claim 21, and further comprising leaving semiconductor material edges on the exterior surfaces of the four sides of the packaged semiconductor devices, the semiconductor material edges spaced from the semiconductor dies by the light blocking material.
